(19) United States
(12) Patent Application Publication
(10) Pub. No.: US 2003/0210068 A1
(43) Pub. Date: Nov. 13, 2003

(54) Apparatus of testing semiconductor

(75) Inventors: Yoshinori Fujiwara, Tokyo (JP); Kazushi Sugiura, Hyogo (JP)

Correspondence Address: McDermott, Will & Emery, 600 13th Street, N.W., Washington, DC, 20005-3096, US

(73) Assignees: Mitsubishi Denki Kabushiki Kaisha; Ryoden Semiconductor System Engineering Corporation

(21) Appl. No.: 10/294,584

(22) Filed: Nov. 15, 2002

(30) Foreign Application Priority Data
May 8, 2002 (JP) 2002-132457

(51) Int. Cl. G01R 31/26

(52) U.S. Cl. 324/765

(57) ABSTRACT

An apparatus and a method for testing a semiconductor that can be subjected to the total test in the state of the final product after sealing in the stage of the wafer test in the test of each of a plurality of semiconductor chips sealed together, and can improve the yield of final products. In the assembly step, another chip sealed together with a chip to be measured is mounted on a probe card, and the tester conducts the test of the chip to be measured through a probe needle connected to the chip to be measured. By transmitting a predetermined command, such as writing and/or reading, from a chip to be measured to another chip, the chip to be measured and the other chip are made to execute operations when these chips are sealed together in a package, and the tester is made to analyze the result of operations and to perform pass or fail judgment.

### BACKGROUND OF THE INVENTION

1. Field of the Invention

The present invention relates to an apparatus of testing a semiconductor, and more specifically to an apparatus of testing a semiconductor for testing each of a plurality of semiconductor chips packaged together.

2. Description of Related Art

Conventionally, each of a plurality of semiconductor chips packaged together was tested in the stage of wafer test by bringing a probe needle or the like into contact with a bonding pad of a wafer chip. Thereafter, only non-defective chips were sealed in a package in the assembly step, and final quality was determined by conducting the total quality test.

However, in the above-described conventional testing method, there was a problem in that although the operation of each chip could be tested in the test of each chip before sealing a plurality of chips together, the total test could not be conducted in the state of a final product after sealing. Therefore, there were items and operations that could not be tested in each device, and devices having defective circuits involved in these items and operations went to the assembly step and the steps to follow. As a result, there was a problem in that these products were judged to be defective, and the yield of final products was lowered.

### SUMMARY OF THE INVENTION

Therefore, in order to solve the above-described problems, the object of the present invention is to provide an apparatus for testing a semiconductor that can be subjected to the total test in the state of the final product after sealing in the stage of the wafer test in the test of each of a plurality of semiconductor chips sealed together, and can improve the yield of final products.

According to a first aspect of the present invention, there is provided a semiconductor testing apparatus for testing a chip to be measured on a wafer comprising: a probe card for carrying another chip to be sealed together with the chip to be measured in a package; and a tester for testing the chip to be measured, wherein the other chip carried by the probe card is connected to the chip to be measured, and the tester is connected to the chip to be measured via the probe card.

According to a second aspect of the present invention, there is provided a semiconductor testing apparatus for testing a chip to be measured on a wafer comprising: a probe card for carrying another chip to be sealed together with the chip to be measured in a package, and a switching circuit for performing a predetermined switching operation; and a tester for testing the chip to be measured, wherein the switching circuit switches connections between the chip to be measured and the tester, between the chip to be measured and the other chip, and between the other chip and the tester.

According to a third aspect of the present invention, there is provided a semiconductor testing method for conducting the test of a chip to be measured on a wafer using a semiconductor testing apparatus, the semiconductor testing apparatus comprises a probe card for carrying another chip to be sealed together with the chip to be measured in a package, and a tester for testing the chip to be measured, the other chip carried by the probe card is connected to the chip to be measured, and the tester is connected to the chip to be measured via the probe card; the semiconductor testing method comprising: a testing step for making the chip to be measured and the other chip perform operations when sealed together in a package by transmitting a predetermined command from the chip to be measured to the other chip; and a step for making the tester determine the result of operation of the chip to be measured in the testing step.

The above and other objects, effects, features and advantages of the present invention will become more apparent from the following description of the embodiments thereof taken in conjunction with the accompanying drawings.

### BRIEF DESCRIPTION OF THE DRAWINGS

FIGS. 1A and 1B illustrate a semiconductor testing apparatus 10 and a semiconductor testing method according to First Embodiment of the present invention.

FIGS. 2A and 2B illustrate a semiconductor testing apparatus 40 and a semiconductor testing method according to Second Embodiment of the present invention.

### DETAILED DESCRIPTION OF THE PREFERRED EMBODIMENTS

Embodiments of the present invention will be described below with reference to the accompanying drawings. It is noted that the same reference symbols in the drawings denote the same or corresponding components.

First Embodiment

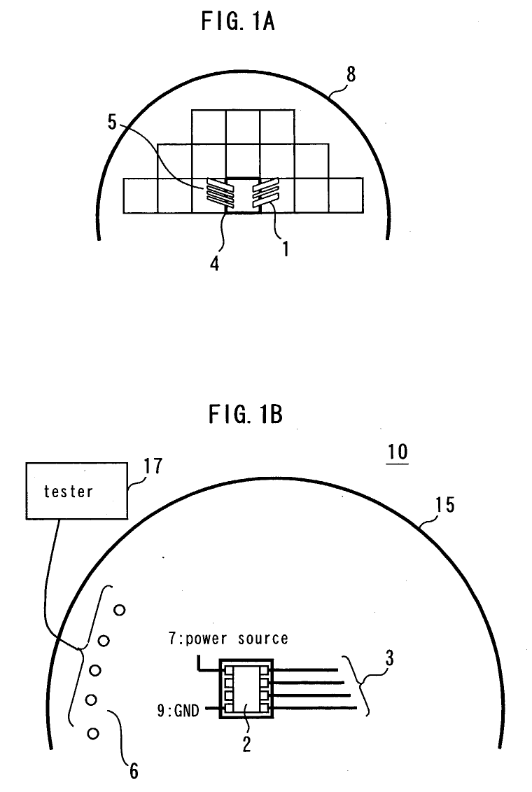

FIGS. 1A and 1B illustrate a semiconductor testing apparatus 10 and a semiconductor testing method according to First Embodiment of the present invention. FIG. 1A shows a wafer 8 having chips subjected to the test by the semiconductor testing apparatus 10 (chips to be measured) 4, and FIG. 1B shows a probe card 15 having conductive needles and the like arranged corresponding to the arrangement of bonding pads for connecting chips to be measured 4 to the tester 17 of the semiconductor testing apparatus 10. The probe card 15 shown in FIG. 1B is mounted on the wafer 10 shown in FIG. 1A.

In FIG. 1A, the reference numeral 8 denotes the above-described wafer, 4 denotes chips to be measured on the wafer 8, 1 denotes probe needles connected to bonding pads (not shown) of chips to be measured 4, and 5 denotes probe needles connected to the tester 17 from the pads 6 described below via the probe card 15. In FIG. 1B, the reference numeral 15 denotes the above-described probe card, 2 denotes another chip sealed simultaneously or together with chips to be measured 4, 7 denotes the power source of the other chip 2, 9 denotes the GND of the other chip 2, 3 denotes signal lines for connecting the other chip 2 to probe needles 1, and 6 denotes pads for connecting the probe needles 5 to the tester 17.

Next, a semiconductor testing method according to First Embodiment using the semiconductor testing apparatus 10 will be described. In this testing method, as FIGS. 1A and 1B illustrate, the test of the chips to be measured 4 is performed through probe needles 5 using the tester 17. Specifically, by transmitting a predetermined command, such as writing and/or reading, from a chip to be measured 4 to another chip 2, the chip to be measured 4 and the other chip 2 are made to execute operations when these chips are sealed together in a package (testing step). Thereafter, the tester 17 analyzes the result of operations by the chip to be measured 4, and performs pass or fail judgment. As a result, the total test in the state of the final product after sealing can be performed between the chip to be measured 4 and the other chip 2 mounted on the probe card 15 in the stage of the wafer test. Therefore, since a defective device is prevented from going to the assembly step and steps to follow, which could not be found in the stage of the wafer test of conventional testing methods, the yield of final products can be improved.

The above-described other chip 2 can be mounted replaceably on the probe card 15. Therefore, if the other chip 2 on the probe card 15 is defective, it can be replaced easily to a new chip. As the other chip 2, a memory device or a logic device comprising a DRAM, a FLASH, or an SRAM. Although the case of one chip to be measured 4 is described in the above-described example, the number of the chip to be measured 4 can be more than one. In this case, the number of other chips 2 and signal lines 3 corresponding to the number of the chips to be measured 4 can be mounted on the probe card 15.

According to First Embodiment, as described above, a chip to be measured 4 and another chip 2 to be sealed simultaneously or together can be mounted on a probe card 15, and the test of the chip to be measured 4 can be conducted from the tester 17 through the probe needle 5 connected to the chip to be measured 4. By transmitting a predetermined command, such as writing and/or reading, from the chip to be measured 4 to the other chip 2, the chip to be measured 4 and the other chip 2 are made to execute operations when sealed together in a package, the chip to be measured 4 is made to output the operations of the chip to be measured 4 and the other chip 2, the tester 17 is made to judge the result of the operations, and pass or fail judgment is performed. As a result, the total test in the state of the final product after sealing can be conducted in the stage of wafer testing between the chip to be measured 4 and another chip 2 mounted on the probe card 15. Therefore, since defect devices are prevented from going to the assembly step and the following steps, which could not be found in the stage of wafer testing as in conventional testing methods.

Second Embodiment

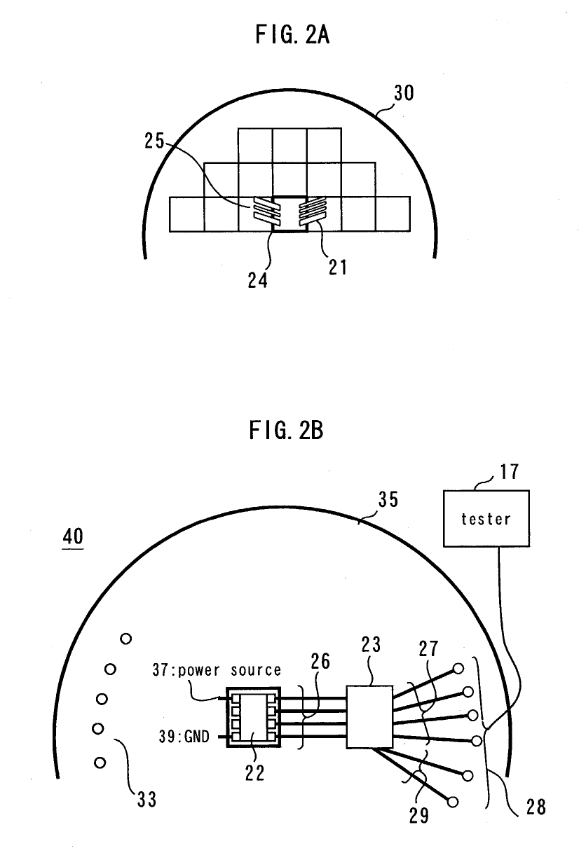

FIGS. 2A and 2B illustrate a semiconductor testing apparatus 40 and a semiconductor testing method according to Second Embodiment of the present invention. FIG. 2A shows a wafer 30 having chips subjected to the test by the semiconductor testing apparatus 40 (chips to be measured) 24, and FIG. 2B shows a probe card 35 having conductive needles and the like arranged corresponding to the arrangement of bonding pads for connecting chips to be measured 24 to the tester 17 of the semiconductor testing apparatus 40. The probe card 35 shown in FIG. 2B is mounted on the wafer 30 shown in FIG. 2A.

In FIG. 2A, the reference numeral 30 denotes the above-described wafer, 24 denotes chips to be measured on the wafer 30, and 21 denotes probe needles connected to bonding pads (not shown) of chips to be measured 24. In FIG. 2B, the reference numeral 17 denotes a tester; 35 denotes the above-described probe card; 22 denotes another chip sealed simultaneously or together with chips to be measured 24; 37 denotes the power source of the other chip 22; 39 denotes the GND of the other chip 22; 23 denotes a switching circuit for switching the connections between the chip to be measured 24 and the tester 17, between the chip to be measured 24 and the other chip 22, and between the other chip 22 and the tester 17; 26 denotes a signal line connecting the other chip 22 with the chip to be measured 24 through the switching circuit 23 and the probe needle 21; 27 denotes a signal line connecting the switching circuit 23 with the tester 17 through the pad 28; and 29 denotes signal path selecting signals inputted from the tester 17 for making the switching circuit 23 switch and select the signal path such as the signal line 26.

Next, a semiconductor testing method according to Second Embodiment using the semiconductor testing apparatus 40 will be described. In general, when the test is conducted in the state of a wafer, it is first checked whether or not the probe card 35 has accurately contacted the boding pad of the chip to be measured 24. Also in Second Embodiment, when the switching circuit 23 switches connections to the connection between the chip to be measured 24 and the tester 17, that is, when the switching circuit 23 conducts between the signal line 27 and the probe needle 21, it is tested whether or not the probe needle 21 of the probe card 35 has accurately contacted the chip to be measured 24 (inspecting step).

Next, when the switching circuit 23 switches the connections to the connection between the chip to be measured 24 and the other chip 22, that is, when the chip to be measured 24 is connected to the other chip 22 through the probe needle 21 and the signal line 26, the chip to be measured 24 transmits a predetermined command to the other chip 22 to make the chip to be measured 24 and the other chip 22 perform operations when they are sealed together in a package (testing step). Specifically, by transmitting a predetermined command, such as writing and/or reading from the chip to be measured 24 to the other chip 22 to drive the other chip 22, the chip to be measured 24 and the other chip 22 are made to execute operations when they are sealed together in a package, the tester 17 is made to determine the output result of the chip to be measured 24.

As a result, the total test in the state of the final product after sealing can be performed between the chip to be measured 24 and the other chip 22 mounted on the probe card 35 in the stage of the wafer test. Therefore, in Second Embodiment, as in First Embodiment, since a defective device is prevented from going to the assembly step and steps to follow, which could not be found in the stage of the wafer test of conventional testing methods, the yield of final products can be improved. Furthermore, in Second Embodiment, by mounting the above-described switching circuit 23 on the probe card 35, it can be ensured that the probe needle 21 contacts the chip to be measured 24 accurately. Therefore, the stable test can be conducted.

As in First Embodiment, the above-described other chip 22 can be mounted replaceably on the probe card 35. Therefore, if the other chip 22 on the probe card 35 is defective, it can be replaced easily to a new chip. As the other chip 22, a memory device or a logic device including a DRAM, a FLASH, or an SRAM can be used. Although the case of one chip to be measured 24 is described in the above-described example, there may be a plurality of chips to be measured 24. In this case, a number of other chips 22, signal lines 26, and the like corresponding to the number of the chips to be measured 24 can be mounted on the probe card 35.

The signals for controlling the chips to be measured 24 that do not use the switching circuit 23 are connected to the tester 17 using probe needles 25 through the probe card 35 and pads 33.

According to Second Embodiment, as described above, the total test in the state of the final product after sealing can be conducted in the stage of wafer testing between the chip to be measured 24 and another chip 22 mounted on the probe card 35 as in First Embodiment. Furthermore, a switching circuit 23 for switching the connections between the chip to be measured 24 and the tester 17, between the chip to be measured 24 and the other chip 22, and between the other chip 22 and the tester 17 can be mounted on the probe card 35. Therefore, since it can be ensured that the probe needle 21 contacts the chip to be measured 24 accurately, the stable test can be conducted.

According to one aspect of the present invention, there is provided a semiconductor testing method for conducting the test of a chip to be measured on a wafer using a semiconductor testing apparatus, the semiconductor testing apparatus comprises a probe card for carrying another chip to be sealed together with the chip to be measured in a package and a switching circuit for performing a predetermined switching operation, a tester for testing the chip to be measured, the switching circuit switches connections between the chip to be measured and the tester, between the chip to be measured and the other chip, and between the other chip and the tester; the semiconductor testing method comprising: a inspecting step for inspecting whether the probe needle of the probe card contacts the chip to be measured when the switching circuit switches so as to connect the chip to be measured to the tester, a testing step for determining a chip to be measured that makes the chip to be measured and the other chip execute operations when these chips are sealed together in a package by transmitting a predetermined command from the chip to be measured to the other chip when the switching circuit switches so as to connect the chip to be measured to the other chip; and a step for determining that the other chip is non-defective by conducting the operation test of the other chip using the tester when the switching circuit switches so as to connect the other chip to the tester.

As described above, according to the semiconductor testing apparatus and the semiconductor testing method of the present invention, the other chip 2 sealed together with the chip to be measured 4 in a package can be mounted on the probe card 15, and the test of the chip to be measured 4 can be conducted by the tester 17 through the probe needle 5 connected to the chip to be measured 4. By transmitting a predetermined command, such as writing and/or reading, from a chip to be measured 4 to another chip 2, the chip to be measured 4 and the other chip 2 are made to execute operations when these chips are sealed together in a package, and the tester 17 is made to analyze the result of operations and to perform pass or fail judgment. Therefore, in the test of semiconductor chips packaged together, the present invention can provide a semiconductor testing apparatus and a semiconductor testing method that can conduct the total test in the state of the final product after sealing, and can improve the yield of final products.

In the semiconductor testing apparatus, the other chip may be a memory device or a logic device including a DRAM, a FLASH, or an SRAM.

In the semiconductor testing apparatus, the other chip may be replaceably mounted on the probe card.

In the semiconductor testing apparatus, the other chips and/or the switching circuits may be mounted in the number corresponding to the number of the chips to be measured.

The present invention has been described in detail with respect to various embodiments, and it will now be apparent from the foregoing to those skilled in the art that changes and modifications may be made without departing from the invention in its broader aspects, and it is the invention, therefore, in the appended claims to cover all such changes and modifications as fall within the true spirit of the invention.

The entire disclosure of Japanese Patent Application No. 2002-132457 filed on May 8, 2002 including specification, claims, drawings and summary are incorporated herein by reference in its entirety.

What is claimed is:

1. A semiconductor testing apparatus for testing a chip to be measured on a wafer comprising:
a probe card for carrying another chip to be sealed together with said chip to be measured in a package; and
a tester for testing said chip to be measured,
wherein the other chip carried by said probe card is connected to said chip to be measured, and said tester is connected to said chip to be measured via said probe card.

2. The semiconductor testing apparatus according to claim 1, wherein said other chip is a memory device or a logic device including a DRAM, a FLASH, or an SRAM.

3. The semiconductor testing apparatus according to claim 1, wherein said other chip is replaceably mounted on said probe card.

4. The semiconductor testing apparatus according to claim 1, wherein said other chips and/or said switching circuits are mounted in the number corresponding to the number of said chips to be measured.

5. A semiconductor testing apparatus for testing a chip to be measured on a wafer comprising:
a probe card for carrying another chip to be sealed together with said chip to be measured in a package, and a switching circuit for performing a predetermined switching operation; and
a tester for testing said chip to be measured,
wherein said switching circuit switches connections between said chip to be measured and said tester, between said chip to be measured and said other chip, and between said other chip and said tester.

6. The semiconductor testing apparatus according to claim 5, wherein said other chip is a memory device or a logic device including a DRAM, a FLASH, or an SRAM.

7. The semiconductor testing apparatus according to claim 5, wherein said other chip is replaceably mounted on said probe card.

8. The semiconductor testing apparatus according to claim 5, wherein said other chips and/or said switching circuits are mounted in the number corresponding to the number of said chips to be measured.
